(19) United States
(12) Patent Application Publication
(10) Pub. No.: US 2022/0403518 A1
(43) Pub. Date: Dec. 22, 2022

(54) SHOWER HEAD AND PLASMA PROCESSING APPARATUS

(71) Applicant: TOKYO ELECTRON LIMITED, Tokyo (JP)

(72) Inventors: Hisashi HIROSE, Miyagi (JP); Hiroshi TSUJIMOTO, Miyagi (JP); Tomoya UJIIE, Miyagi (JP)

(73) Assignee: TOKYO ELECTRON LIMITED, Tokyo (JP)

(21) Appl. No.: 17/845,354

(22) Filed: Jun. 21, 2022

(30) Foreign Application Priority Data
Jun. 22, 2021 (JP) 2021-103225

(51) Int. Cl. C23C 16/455; H01J 37/32

(52) U.S. Cl. CPC C23C 16/45565; H01J 37/3244; C23C 16/45572; H01J 37/32532

(57) ABSTRACT

There is a shower head through which a processing gas is supplied into an inside of a processing chamber, comprising: a cooling plate having a gas diffusion chamber, and a plurality of first through holes passing through from the gas diffusion chamber to a first surface on a processing chamber side; an upper electrode having a second surface in contact with the first surface of the cooling plate, a third surface configured to form an inner surface of the processing chamber, and a plurality of second through holes passing through from the second surface to the third surface; and a plurality of recesses formed in the first surface or the second surface and provided apart from each other, wherein one of the plurality of first through holes is connected to at least two of the plurality of second through holes via one of the plurality of recesses.

### CROSS-REFERENCE TO RELATED APPLICATIONS

This application claims priority to Japanese Patent Application No. 2021-103225 filed on Jun. 22, 2021, the entire contents of which are incorporated herein by reference.

### TECHNICAL FIELD

The present disclosure relates to a shower head and a plasma processing apparatus.

### BACKGROUND

In a plasma processing apparatus, a shower head is used to supply a processing gas into a processing chamber (for example, Japanese Laid-open Patent Publication No. 2010-514160).

### SUMMARY

The present disclosure is directed to providing a technique for preventing abnormal discharge from occurring inside a shower head.

In accordance with an aspect of the present disclosure, there is a shower head through which a processing gas is supplied into an inside of a processing chamber, comprising: a cooling plate having a gas diffusion chamber, and a plurality of first through holes passing through from the gas diffusion chamber to a first surface on a processing chamber side and through which the processing gas flows; an upper electrode having a second surface in contact with the first surface of the cooling plate, a third surface configured to form an inner surface of the processing chamber, and a plurality of second through holes passing through from the second surface to the third surface; and a plurality of recesses formed in the first surface or the second surface and provided apart from each other, wherein one of the plurality of first through holes is connected to at least two of the second through holes of the plurality of second through holes via one of the plurality of recesses.

### BRIEF DESCRIPTION OF THE DRAWINGS

FIG. 1 is a diagram showing a configuration example of an example of a plasma processing system according to the present embodiment.

FIG. 2 is a plan view of an upper electrode in an example of a shower head of a plasma processing apparatus according to a first embodiment.

FIG. 3 is a cross-sectional view of an example of the shower head of the plasma processing apparatus according to the first embodiment.

FIG. 4 is a plan view of an upper electrode in an example of a shower head of a plasma processing apparatus according to a second embodiment.

FIG. 5 is a plan view of an upper electrode in an example of a shower head of a plasma processing apparatus according to a third embodiment.

FIG. 6 is a diagram showing a temperature distribution in an example of the shower head of the plasma processing apparatus according to the present embodiment.

FIG. 7 is a diagram showing operation results of an example of the plasma processing apparatus according to the present embodiment.

FIG. 8 is a diagram showing operation results of an example of the plasma processing apparatus according to the present embodiment.

FIG. 9 is a diagram showing operation results of an example of the plasma processing apparatus according to the present embodiment.

FIG. 10 is a diagram showing operation results of a plasma processing apparatus according to a reference example.

FIG. 11 is a diagram showing operation results of a plasma processing apparatus according to the reference example.

### DETAILED DESCRIPTION

Hereinafter, embodiments for implementing the present disclosure will be described with reference to the accompanying drawings. In the specification and the drawings, substantially the same constituents are designated by the same reference numerals and duplicate description is omitted. For ease of understanding, the scale of each part in the drawing may differ from the actual scale.

In parallel, perpendicular, orthogonal, horizontal, vertical, up and down, left and right directions, and the like, a deviation that does not impair the effects of the embodiments is allowed. A shape of a corner portion is not limited to a right angle and may be rounded in a bow shape. The terms “parallel”, “perpendicular”, “orthogonal”, “horizontal”, and “vertical” may include substantially parallel, substantially right-angled, substantially orthogonal, substantially horizontal, and substantially vertical.

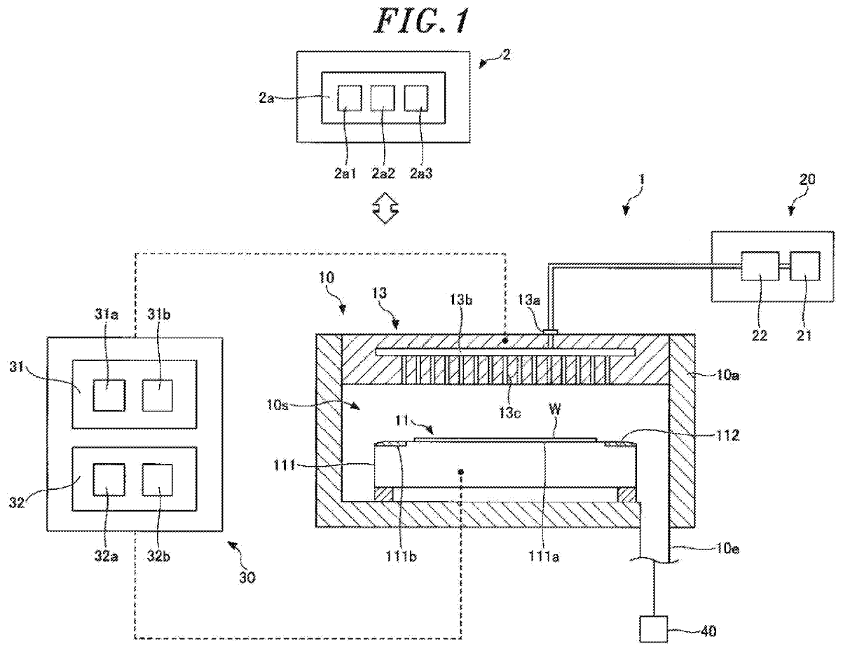

Hereinafter, a configuration example of a plasma processing system will be described with reference to FIG. 1.

The plasma processing system includes a capacitive coupling plasma processing apparatus 1 and a controller 2. The capacitive coupling plasma processing apparatus 1 includes a plasma processing chamber 10, a gas supply 20, a power source 30, and an exhaust system 40. Further, the plasma processing apparatus 1 includes a substrate support 11 and a gas introduction part. The gas introduction part is configured to introduce at least one processing gas into the plasma processing chamber 10. The gas introduction part includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas discharge port for discharging the gas from the plasma processing space. The side wall 10a is grounded. The shower head 13 and the substrate support 11 are electrically insulated from a housing of the plasma processing chamber 10. As will be described below, the shower head 13 includes a cooling plate and an upper electrode.

The substrate support 11 includes a main body 111 and a ring assembly 112. The main body 111 has a central region (a substrate support surface) 111a for supporting a substrate (a wafer) W and an annular region (a ring support surface) 111b for supporting the ring assembly 112. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. In one embodiment, the main body 111 includes a base and an electrostatic chuck. The base includes a conductive member. The conductive member of the base serves as a lower electrode. The electrostatic chuck is disposed on the base. An upper surface of the electrostatic chuck has the substrate support surface 111a. The ring assembly 112 includes one or more annular members. At least one of the one or more annular members is an edge ring. Further, although not shown, the substrate support 11 may include a temperature control module configured to adjust at least one of the electrostatic chuck, the ring assembly 112, and the substrate to a target temperature. The temperature control module may include a heater, a heat transfer medium, a flow path, or a combination thereof. A heat transfer fluid such as brine and gas flow through the flow path. Further, the substrate support 11 may include a heat transfer gas supply configured to supply a heat transfer gas between a back surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 serves as an upper electrode. In addition to the shower head 13, the gas introduction part may include one or more side gas injectors (SGIs) mounted in one or more openings formed in the side wall 10a.

The gas supply 20 may include at least one gas source 21 and at least one flow rate controller 22. In one embodiment, the gas supply 20 is configured to supply at least one processing gas from the corresponding gas source 21 to the shower head 13 via the corresponding flow rate controller 22. Each of the flow rate controllers 22 may include, for example, a mass flow controller or a pressure-controlled flow rate controller. Further, the gas supply 20 may include one or more flow rate modulation devices that modulate or pulse a flow rate of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the shower head 13. Thus, plasma is formed from at least one processing gas supplied to the plasma processing space 10s. Therefore, the RF power source 31 may serve as at least a part of a plasma generator configured to generate plasma from one or more processing gases in the plasma processing chamber 10. Further, a bias potential is generated in the substrate W by supplying the bias RF signal to the conductive member of the substrate support 11, and an ionic component in the formed plasma can be attracted to the substrate W.

In one embodiment, the RF power source 31 includes a first RF generator 31a and a second RF generator 31b. The first RF generator 31a is coupled to the conductive member of the substrate support 11 and/or the conductive member of the shower head 13 via at least one impedance matching circuit and is configured to generate a source RF signal (source RF power) for plasma generation. In one embodiment, the source RF signal has a frequency in a range of 13 MHz to 150 MHz. In one embodiment, the first RF generator 31a may be configured to generate a plurality of source RF signals with different frequencies. The one or more generated source RF signals are supplied to the conductive member of the substrate support 11 and/or the conductive member of the shower head 13. The second RF generator 31b is coupled to the conductive member of the substrate support 11 via at least one impedance matching circuit and is configured to generate a bias RF signal (bias RF power). In one embodiment, the bias RF signal has a lower frequency than the source RF signal. In one embodiment, the bias RF signal has a frequency in a range of 400 kHz to 13.56 MHz. In one embodiment, the second RF generator 31b may be configured to generate a plurality of bias RF signals with different frequencies. The one or more generated bias RF signals are supplied to the conductive member of the substrate support 11. Also, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and is configured to generate a first DC signal. The generated first bias DC signal is applied to the conductive member of the substrate support 11. In one embodiment, the first DC signal may be applied to another electrode such as an electrode in the electrostatic chuck. In one embodiment, the second DC generator 32b is connected to the conductive member of the shower head 13 and is configured to generate a second DC signal. The generated second DC signal is applied to the conductive member of the shower head 13. In various embodiments, at least one of the first and second DC signals may be pulsed. The first and second DC generators 32a and 32b may be provided in addition to the RF power source 31, and the first DC generator 32a may be provided in place of the second RF generator 31b.

The exhaust system 40 may be connected to, for example, a gas discharge port 10e provided in a bottom of the plasma processing chamber 10. The exhaust system 40 may include a pressure adjustment valve and a vacuum pump. The pressure in the plasma processing space 10s is adjusted by the pressure adjustment valve. The vacuum pump may include a turbo molecular pump, a dry pump or a combination thereof.

The controller 2 processes computer-executable instructions that cause the plasma processing apparatus 1 to perform various steps described in the present disclosure. The controller 2 may be configured to control each element of the plasma processing apparatus 1 to perform the various steps described herein. In one embodiment, a part or all of the controller 2 may be included in the plasma processing apparatus 1. The controller 2 may include, for example, a computer 2a. The computer 2a may include, for example, a central processing unit (CPU) 2a1, a storage part 2a2, and a communication interface 2a3. The CPU 2a1 may be configured to perform various control operations based on a program stored in the storage part 2a2. The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### First Embodiment

[Shower Head 13]

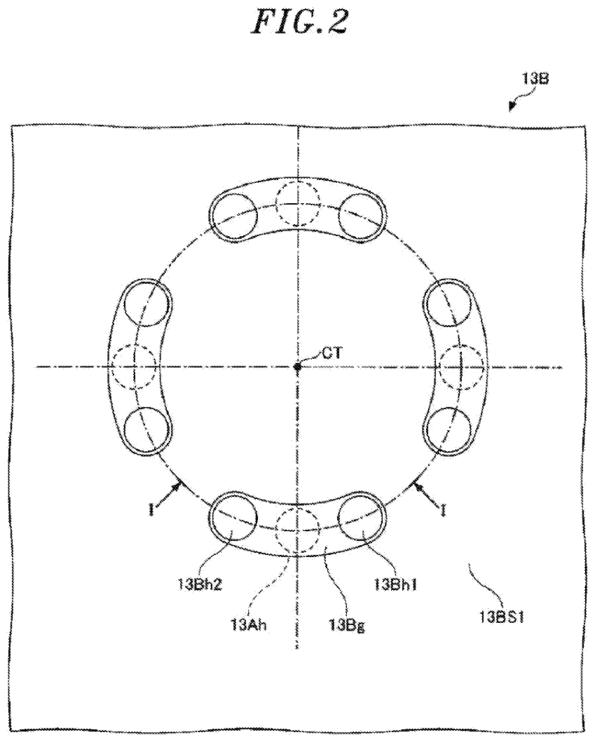

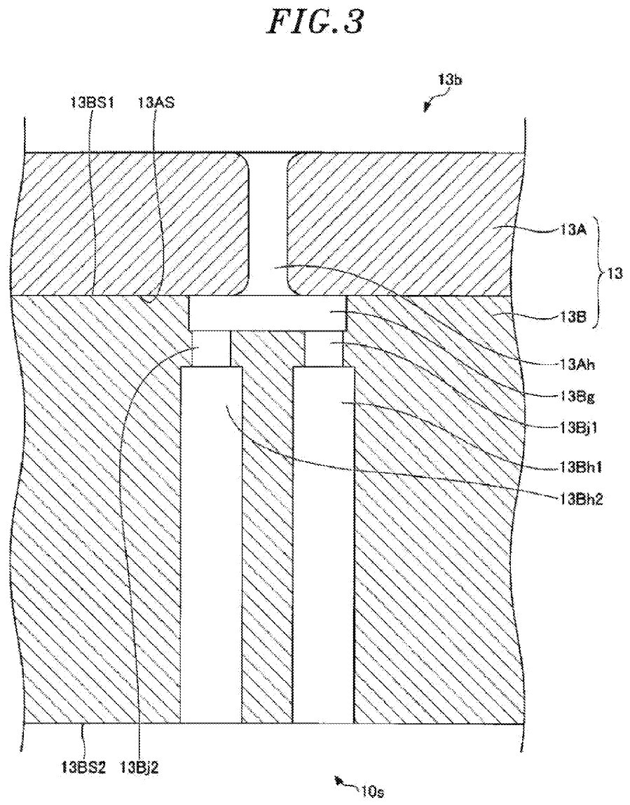

FIG. 2 is a plan view of an upper electrode 13B of the shower head 13 according to a first embodiment. FIG. 3 is a cross-sectional view of the shower head 13 according to the first embodiment. Specifically, FIG. 3 is a cross-sectional view taken along line I-I of FIG. 2.

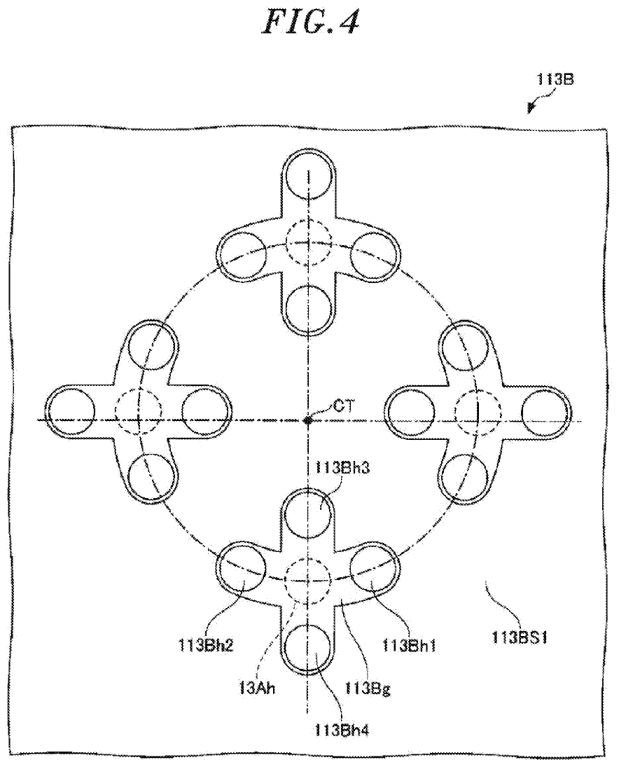

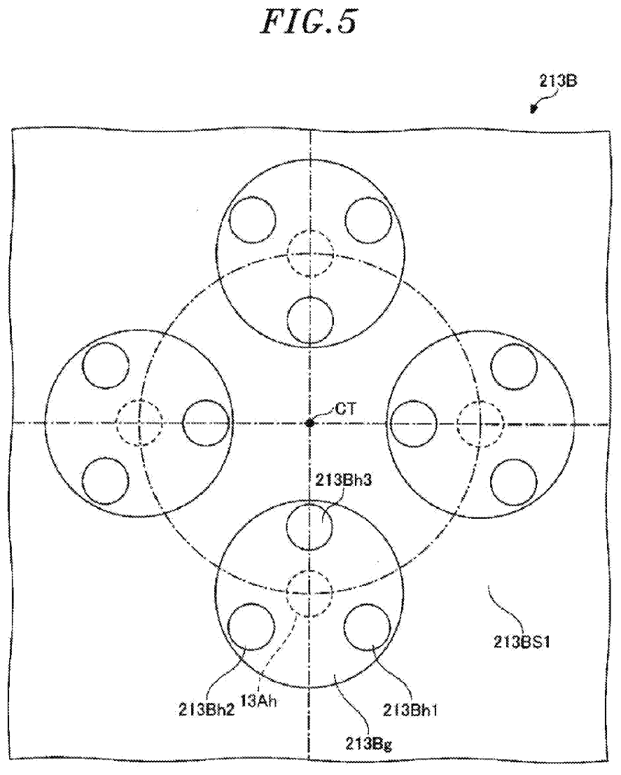

The shower head 13 includes a plurality of recesses 13Bg in each of a plurality of concentric circles. The shower head 13 has a plurality of through holes 13Ah, 13Bh1 and 13Bh2 corresponding to the recesses 13Bg. FIG. 2 shows, for example, the recesses 13Bg provided on one concentric circle, with respect to the plurality of recesses 13Bg provided on the concentric circles. The same applies to FIGS. 4 and 5.

The shower head 13 supplies a processing gas to the inside of the plasma processing chamber 10. The shower head 13 includes a cooling plate 13A and the upper electrode 13B.

The cooling plate 13A cools the entire shower head 13. The cooling plate 13A is made of, for example, aluminum. For example, a flow path through which water, antifreeze, or the like flows is formed in the cooling plate 13A. The cooling plate 13A has a gas diffusion chamber 13b. A lower surface 13AS of the cooling plate 13A on the plasma processing space 10s side, that is, a surface on the processing chamber side is in contact with the upper electrode 13B.

The cooling plate 13A has a through hole 13Ah passing through from the gas diffusion chamber 13b to the lower surface 13AS. The processing gas introduced into the gas diffusion chamber 13b is discharged to the upper electrode 13B side through the through hole 13Ah. That is, the processing gas flows through the through hole 13Ah.

The upper electrode 13B is an electrode that supplies high frequency power to the plasma processing space 10s. The upper electrode 13B is made of, for example, silicon. An upper surface 13BS1 of the upper electrode 13B is in contact with the cooling plate 13A. A lower surface 13BS2 of the upper electrode 13B is in contact with the plasma processing space 10s. That is, the lower surface 13BS2 of the upper electrode 13B forms an inner surface of the plasma processing space 10s.

The upper electrode 13B has the plurality of recesses 13Bg in the upper surface 13BS1. Each of the plurality of recesses 13Bg is formed in an arc shape in a circumferential direction with respect to a center CT. The plurality of recesses 13Bg are provided apart from each other. Any one of the plurality of through holes 13Ah of the cooling plate 13A is connected to each of the plurality of recesses 13Bg. The through hole 13Ah is connected to a center of the recess 13Bg.

The upper electrode 13B has through holes 13Bh1 and through holes 13Bh2 pass through from a bottom portion of each of the recesses 13Bg to the lower surface 13BS2 in each of the plurality of recesses 13Bg. The through hole 13Bh1 has a throttle portion 13Bj1 at a connection portion with the recess 13Bg. The through hole 13Bh2 has a throttle portion 13Bj2 at a connection portion with the recess 13Bg.

The through hole 13Bh1 and the through hole 13Bh2 are provided at end portions of each of the recesses 13Bg.

The plasma processing gas supplied to the gas diffusion chamber 13b is introduced into the recess 13Bg from the through hole 13Ah. Then, the plasma processing gas introduced into the recess 13Bg is branched off into the through hole 13Bh1 and the through hole 13Bh2 at the recess 13Bg and is introduced into the plasma processing space 10s. That is, the processing gas flows through the through hole 13Bh1 and the through hole 13Bh2 via the recess 13Bg.

The shower head 13 can lower a pressure of the plasma processing gas at a boundary between the cooling plate 13A and the upper electrode 13B by branching the plasma processing gas supplied into the gas diffusion chamber 13b from the through hole 13Ah at the recess 13Bg. It is possible to prevent the occurrence of abnormal discharge at the boundary between the cooling plate 13A and the upper electrode 13B by lowering the pressure of the plasma processing gas.

The recess 13Bg is not limited to the arc shape and may be provided to have a straight line shape. Further, although the recesses 13Bg are formed in the circumferential direction, the recesses may be formed in a radial direction.

### Second Embodiment

[Shower Head 113]

FIG. 4 is a plan view of an upper electrode 113B of a shower head according to a second embodiment. The shower head according to the second embodiment includes an upper electrode 113B instead of the upper electrode 13B of the shower head 13 according to the first embodiment.

The upper electrode 113B has a recess 113Bg instead of the recess 13Bg of the upper electrode 13B. The upper electrode 113B has a plurality of recesses 113Bg in an upper surface 113BS1. Each of the plurality of recesses 113Bg is formed in a cross shape. That is, with respect to the center CT, an arc-shaped groove formed in the circumferential direction and a linear groove formed in the radial direction are formed in combination. Any one of the plurality of through holes 13Ah of the cooling plate 13A is connected to each of the plurality of recesses 113Bg. The through hole 13Ah is connected to a center of the recess 113Bg.

The upper electrode 113B has a through hole 113Bh1, a through hole 113Bh2, a through hole 113Bh3, and a through hole 113Bh4 passing through from a bottom portion of each of the plurality of recesses 113Bg to a lower surface in contact with the plasma processing space 10s. Each of the through hole 113Bh1, the through hole 113Bh2, the through hole 113Bh3, and the through hole 113Bh4 has a throttle portion at a connection portion with the recess 113Bg.

Each of the through hole 113Bh1, the through hole 113Bh2, the through hole 113Bh3 and the through hole 113Bh 4 are provided at an end of the recess 113Bg.

The plasma processing gas supplied into the gas diffusion chamber 13b is introduced into the recess 113Bg from the through hole 13Ah. Then, the plasma processing gas introduced into the recess 113Bg is branched off into the through hole 113Bh1, the through hole 113Bh2, the through hole 113Bh3, and the through hole 113Bh4 at the recess 113Bg, and is introduced into the plasma processing space 10s.

The shower head according to the second embodiment can reduce the pressure of the plasma processing gas at the boundary between the cooling plate 13A and the upper electrode 113B by branching the plasma processing gas supplied into the gas diffusion chamber 13b from the through hole 13Ah at the recess 113Bg. It is possible to prevent the occurrence of abnormal discharge at the boundary between the cooling plate 13A and the upper electrode 113B by lowering the pressure of the plasma processing gas.

### Third Embodiment

[Shower Head 213]

FIG. 5 is a plan view of an upper electrode 213B of a shower head according to a third embodiment. The cooling plate of the shower head according to the third embodiment includes an upper electrode 213B instead of the upper electrode 13B of the shower head 13 according to the first embodiment.

The upper electrode 213B has a recess 213Bg instead of the recess 13Bg of the upper electrode 13B. The upper electrode 213B has a plurality of recesses 213Bg on a circumference with the center CT in an upper surface 213BS1 thereof. Each of the plurality of recesses 213Bg is formed in a cylindrical shape. Any one of the plurality of through holes 13Ah of the cooling plate 13A is connected to each of the plurality of recesses 213Bg. The through hole 13Ah is connected to the center of the recess 213Bg.

The upper electrode 213B has a through hole 213Bh1, a through hole 213Bh2, and a through hole 213Bh3 passing through from a bottom portion of each of the plurality of recesses 213Bg to a lower surface in contact with the plasma processing space 10s in each of the plurality of recesses 213Bg. Each of the through hole 213Bh1, the through hole 213Bh2, and the through hole 213Bh3 has a throttle portion at a connection portion with the recess 213Bg.

The through hole 213Bh1, the through hole 213Bh2, and the through hole 213Bh3 are provided at equal distances from the through hole 13Ah.

The plasma processing gas supplied into the gas diffusion chamber 13b is introduced into the recess 213Bg from the through hole 13Ah. Then, the plasma processing gas introduced into the recess 213Bg is branched off into the through hole 213Bh1, the through hole 213Bh2 and the through hole 213Bh3 at the recess 213Bg and is introduced into the plasma processing space 10s.

The shower head according to the third embodiment can reduce the pressure of the plasma processing gas at the boundary between the cooling plate 13A and the upper electrode 213B by branching the plasma processing gas supplied into the gas diffusion chamber 13b from the through hole 13Ah at the recess 213Bg. It is possible to prevent the occurrence of abnormal discharge at the boundary between the cooling plate 13A and the upper electrode 213B by lowering the pressure of the plasma processing gas.

### Effects of Temperature Due to Recess of Upper Electrode

When plasma is generated in the plasma processing space 10s, heat from the plasma enters the upper electrode. When heat from the plasma enters the upper electrode, a temperature of the upper electrode rises. When the temperature of the upper electrode rises, degradation of the upper electrode progresses, and a replacement cycle becomes shorter. Therefore, in order to suppress the temperature rise of the upper electrode, the upper electrode is cooled by the cooling plate.

When the recess is provided on the upper surface of the upper electrode, thermal resistance between the upper electrode and the cooling plate increases. Therefore, ability of the cooling plate to cool the upper electrode is reduced.

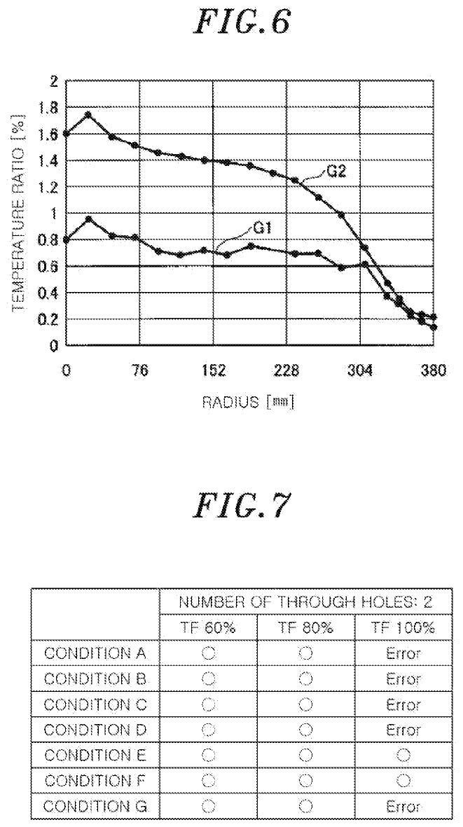

FIG. 6 shows results of simulating an effect of the recess of the upper electrode on the cooling of the upper electrode.

The simulation was performed on a disk-shaped upper electrode having a radius of 380 mm. The simulation was performed on three models including a reference model, an example model, and a comparative example model for the upper electrode. In the simulation, the upper surface of the upper electrode was cooled by a cooling plate, and a temperature distribution of the upper electrode was obtained when heat was input from the plasma processing space side, that is, a lower surface of the upper electrode. In the simulation, a material of the upper electrode was silicon.

The reference model is a model of the upper electrode having no recess on the upper surface of the upper electrode.

The example model is a model of the upper electrode in which a recess corresponding to the recess 13Bg of the shower head 13 of the first embodiment is formed in the upper surface of the upper electrode. In the example model, a plurality of recesses are provided at intervals on 16 concentric circles. The 16 concentric circles are provided at equal intervals inside a radius of 300 mm.

The comparative example model is a model of the upper electrode in which recesses are formed on 16 concentric circles on the upper surface of the upper electrode. In the comparative example model, the recesses are provided over the entire circumference. The 16 concentric circles are provided at equal intervals inside a radius of 300 mm.

Heat dissipation characteristics of the upper electrode having the recesses are evaluated using the simulation. In this evaluation, the evaluation was performed using a ratio (a temperature ratio) of the increased temperature in the example model and the comparative example model to the temperature of the reference model in a radial position. FIG. 6 is a diagram showing a temperature distribution of an example of a shower head of the plasma processing apparatus according to the present embodiment. A line G1 in a graph is a result in the example model. A line G2 is a result of the comparative example model.

When the recesses are provided on the entire circumference as in the comparative example model, the thermal resistance between the upper electrode and the cooling plate increases. Therefore, the cooling performance of the cooling plate is lowered, and the temperature of the upper electrode rises. In addition, the temperature rise in the vicinity of the center is large, and heat uniformity is degraded.

In the example model, the temperature rise is suppressed, and the heat uniformity can be improved as compared with the comparative example model. A lifespan of the upper electrode can be increased by suppressing the temperature rise. Further, it is possible to suppress bias of processing performance such as an etching rate depending on locations by improving the heat uniformity.

### Abnormal Discharge Between Upper Electrode and Cooling Plate

The number of through holes in the upper electrode with respect to one through hole in the cooling plate was evaluated for abnormal discharge between the cooling plate and the upper electrode.

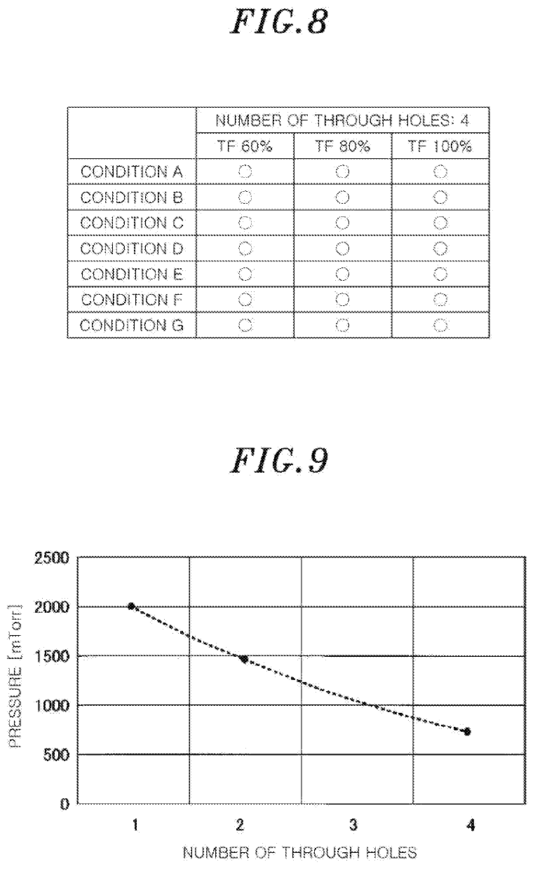

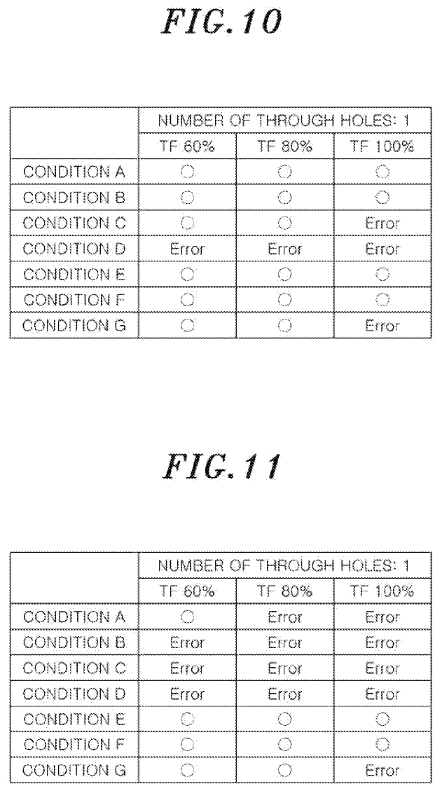

FIG. 7 is a diagram showing an operating state when there are two through holes in the upper electrode with respect to one through hole of the cooling plate. FIG. 8 is a diagram showing an operating state when there are four through holes in the upper electrode with respect to one through hole of the cooling plate. FIGS. 10 and 11 are diagrams showing an operating state when there is one through hole in the upper electrode with respect to one through hole of the cooling plate for comparison. In FIGS. 7, 8, 10 and 11, “Error” indicates that the occurrence of abnormal discharge has been detected.

As an example of plasma processing conditions according to the present embodiment, conditions for etching a silicon oxide film formed on a substrate will be described. The evaluation was performed by performing an etching process in the plasma processing apparatus 1. The evaluation was performed with a pressure of 25 milliTorr (=3.3 pascals) for the plasma processing space 10s and a set temperature of 70° C. for the substrate support 11. Hexafluoro-1,3-butadiene, oxygen, nitrogen and argon were used as the processing gas for evaluation. A flow rate of each of hexafluoro-1,3-butadiene, oxygen, nitrogen and argon used as the processing gas are 70/40/200/800 sccm (maximum flow rate).

Further, the evaluation was performed by supplying a source RF signal having a frequency of 40 MHz and a bias RF signal having a frequency of 400 kHz and a power of 10000 watts from the power source 30 to a substrate holder 116.

Under condition A, a pulse signal having a high level of 4000 watts and a low level of 200 watts was supplied as the source RF signal. Further, under the condition A, a pulsed signal having a high level of −300 volts and a low level of −1000 volts was supplied as a second DC signal.

Under condition B, a pulse signal having a high level of 4000 watts and a low level of 0 watts was supplied as the source RF signal. Further, under the condition B, a pulsed signal having a high level of −150 volts and a low level of −1000 volts was supplied as the second DC signal.

Under condition C, a pulse signal having a high level of 4000 watts and a low level of 0 watts was supplied as the source RF signal. Further, under the condition C, a pulsed signal having a high level of −300 volts and a low level of −1000 volts was supplied as the second DC signal.

Under condition D, a pulse signal having a high level of 4000 watts and a low level of 0 watts was supplied as the source RF signal. Further, under the condition D, a pulsed signal having a high level of −500 volts and a low level of −1000 volts was supplied as the second DC signal.

Under condition E, a pulse signal having a high level of 4000 watts and a low level of 0 watts was supplied as the source RF signal. Further, under the condition E, a signal having a constant voltage of −150 volts was supplied as the second DC signal.

Under condition F, a pulse signal having a high level of 4000 watts and a low level of 0 watts was supplied as the source RF signal. Further, under the condition F, a signal having a constant voltage of −300 volts was supplied as the second DC signal.

Under condition G, a pulse signal having a high level of 4000 watts and a low level of 0 watts was supplied as the source RF signal. Further, under the condition G, a signal having a constant voltage of −500 volts was supplied as the second DC signal.

The conditions A to G are conditions in which pulse conditions and applied voltage conditions are changed. TF indicates a flow rate of the processing gas (a gas flow rate). The gas flow rate is expressed as a ratio (%) to the maximum flow rate in which 100% is the maximum flow rate flowing through the apparatus.

For comparison, FIG. 10 shows a state in which the abnormal discharge occurs in a state in which the voltage applied to the upper electrode is lowered when there is one through hole in the upper electrode with respect to one through hole in the cooling plate. FIG. 11 shows a state in which the abnormal discharge occurs in a state in which the voltage applied to the upper electrode is higher than the state shown in FIG. 10 when there is one through hole in the upper electrode with respect to one through hole in the cooling plate.

As shown in FIG. 10, the abnormal discharge occurs under the condition C, the condition D, and the condition G in a state in which the voltage applied to the upper electrode is lowered when the gas flow rate TF is 100% and there is one through hole in the upper electrode with respect to one through hole of the cooling plate. Regarding the condition D, the abnormal discharge occurs even when the gas flow rate TF is 60% and 80%.

Further, when the voltage applied to the upper electrode is increased, and there is one through hole in the upper electrode with respect to one through hole of the cooling plate, the abnormal discharge occurs under the condition B, the condition C and the condition D when the gas flow rate TF are 60%, 80% and 100% (FIG. 11). Under the condition A, the abnormal discharge occurs when the gas flow rate TF are 80% and 100%. Under the condition G, the abnormal discharge occurs when the gas flow rate TF is 100%.

When there are two through holes in the upper electrode for one through hole in the cooling plate, as shown in FIG. 7, the abnormal discharge occurs under condition A, condition B, condition C, condition D, and condition G in a state in which the voltage applied to the upper electrode is increased when the gas flow rate TF is 100%. The occurrence of abnormal discharge can be suppressed by providing two through holes of the upper electrode with respect to one through hole of the cooling plate, compared with the case in which the upper electrode has one through hole with respect to one through hole of the cooling plate.

Further, when there are four through holes in the upper electrode with respect to one through hole of the cooling plate, the abnormal discharge can be suppressed under all conditions as shown in FIG. 8.

Here, the pressure of the processing gas at a boundary between the through hole of the cooling plate and the through hole of the upper electrode is shown in FIG. 9.

A horizontal axis indicates the number of through holes in the upper electrode with respect to one through hole of the cooling plate. A vertical axis indicates the pressure of the processing gas at the boundary between the through hole of the cooling plate and the through hole of the upper electrode.

The pressure of the processing gas at the boundary between the through hole of the cooling plate and the through hole of the upper electrode decreases as the number of through holes in the upper electrode with respect to one through hole of the cooling plate increases. When the pressure of the processing gas at the boundary between the through hole of the cooling plate and the through hole of the upper electrode decreases, the density of the processing gas decreases, and occurrence of electric discharge can be suppressed. Therefore, the abnormal discharge between the cooling plate and the upper electrode can be suppressed.

### Actions and Effects

The shower head according to the present embodiment can suppress the occurrence of abnormal discharge between the cooling plate and the upper electrode by providing at least two through holes in the upper electrode with respect to one through hole of the cooling plate.

Further, in the shower head according to the present embodiment, the through holes of the cooling plate and the through holes of the upper electrode are connected to each other via recesses provided to be separated from each other. It is possible to suppress the degradation of the cooling performance of the upper electrode due to the cooling plate and to suppress the occurrence of abnormal discharge by connecting the through hole of the cooling plate and the through hole of the upper electrode via the recess.

The through hole 13Ah is an example of a first through hole, and the lower surface 13AS is an example of a first surface. The through holes 13Bh1, 13Bh2, 113Bh1, 113Bh2, 113Bh3, 113Bh4, 213Bh1, 213Bh2, and 213Bh3 are examples of second through holes. Each of the upper surface 13BS1, 113BS1, and 213BS1 is an example of a second surface, and the lower surface 13BS2 is an example of a third surface.

### MODIFIED EXAMPLE

In the present embodiment, the recesses are provided in the upper surface of the upper electrode, but the locations in which the recesses are provided are not limited to the upper electrode. For example, the recesses may be provided in the lower surface of the cooling plate, that is, the surface connected to the upper electrode.

In the present embodiment, an example of two, three and four through holes in the upper electrode for one through hole in the cooling plate is shown, but there may be two or more through holes in the upper electrode with respect to one through hole of the cooling plate. That is, at least two through holes of the upper electrode may be used with respect to one through hole of the cooling plate.

The shower head and the plasma processing apparatus according to the present embodiment disclosed herein should be considered to be exemplary in all respects and not restrictive. The above embodiments can be modified and improved in various ways without departing from the scope of the attached claims and the gist thereof. The details described in the above-described plurality of embodiments may have other configurations within a non-contradictory range and may be combined within a non-contradictory range.

1. A shower head through which a processing gas is supplied into an inside of a processing chamber, comprising:
a cooling plate having a gas diffusion chamber, and a plurality of first through holes passing through from the gas diffusion chamber to a first surface on a processing chamber side and through which the processing gas flows;
an upper electrode having a second surface in contact with the first surface of the cooling plate, a third surface configured to form an inner surface of the processing chamber, and a plurality of second through holes passing through from the second surface to the third surface; and
a plurality of recesses formed in the first surface or the second surface and provided apart from each other,
wherein one of the plurality of first through holes is connected to at least two of the second through holes of the plurality of second through holes via one of the plurality of recesses.

2. The shower head of claim 1, wherein at least one of the plurality of recesses is formed to have an arc shape.

3. The shower head of claim 1, wherein at least one of the plurality of recesses is formed to have a linear shape.

4. The shower head of claim 1, wherein at least one of the plurality of recesses is formed to have a cross shape.

5. The shower head of claim 1, wherein the cooling plate is made of aluminum, and
the upper electrode is made of silicon.

6. A plasma processing apparatus comprising the shower head of claim 1.
